(19) United States
(12) Patent Application Publication
(10) Pub. No.: US 2009/0073885 A1
(43) Pub. Date: Mar. 19, 2009

(54) METHOD, SYSTEM AND APPARATUS FOR TRACKING USER BEHAVIOR IN A WIRELESS COMMUNICATION NETWORK

(76) Inventors: Rehan Jalil, San Jose, CA (US); Mustafa Ergen, Oakland, CA (US); Pawan Uberoy, Milpitas, CA (US)

Correspondence Address: GLOBAL IP SERVICES, PLLC, 10 CRESTWOOD LANE, NASHUA, NH, 03062, US

(21) Appl. No.: 12/211,833

(22) Filed: Sep. 17, 2008

Related U.S. Application Data
(60) Provisional application No. 60/994,141, filed on Sep. 17, 2007.

(51) Int. Cl. G01R 31/08

(52) U.S. Cl. 370/241; 370/338

(57) ABSTRACT

A method, system, and apparatus for tracking user behavior in a wireless communication network are provided. The method includes monitoring one or more data packets communicated between one or more devices and one or more data servers at an anchor datapath gateway in the wireless communication network. The method further includes creating one or more profiles for one or more users in response to monitoring the one or more data packets. The one or more devices are used by the one or more users.

### RELATED APPLICATIONS

Benefit is claimed under 35 U.S.C. 119(e) to U.S. Provisional Applications Ser. No: 60/994,141 entitled “METHOD, SYSTEM AND APPARATUS FOR TRACKING USER BEHAVIOR IN A WIRELESS COMMUNICATION NETWORK” by Rehan Jalil et al., filed on 17th Sep., 2007, which is herein incorporated in its entirety by reference for all purposes.

### FIELD OF THE INVENTION

The present invention generally relates to a wireless communication network. More specifically the present invention relates to tracking user behavior in the wireless communication network.

### BACKGROUND OF THE INVENTION

Wireless networks have become indispensable with the advent of portable communication devices such as web enabled mobile phones, laptop computers, personal digital assistants etc. Working on the move and access to the internet has become essential requirements for the average professional. This need has been met by wireless networks in public modes of transport and at public places such as eateries, parks, malls, etc. Therefore, the user may log into several different wireless networks in a day.

Targeted advertising based on specific characteristics of the user are well known in the art. The specific characteristics may include interests, preferences, location, etc. of the user. This information is usually obtained when the user logs into a network. However, with the wide deployment of wireless networks and their increasing use, targeted advertising is becoming increasingly difficult as user specific information is not always available to the wireless network the user is currently logged on to. Since the user may log into several different wireless networks in a day, the user may not appreciate being asked to specify personal information each time.

Another form of targeted advertising includes presenting advertisements to a user based on the content of the web page currently being viewed by the user. This practice may not be effective. For example, if a user first views a web site about a particular brand of car, the web site may have advertisements related to accessories for the brand of car. If the user selects a particular car and then performs a search for car dealers in the vicinity, the user may be shown car dealers who may or may not stock the particular car selected by the user. Thus, there is no co-relation between content previously viewed by the user and the advertisements presented to the user.

Therefore, there is a need for a method and system for gathering sufficient user specific information.

### BRIEF DESCRIPTION OF THE DRAWINGS

The accompanying figures where like reference numerals refer to identical or functionally similar elements throughout the separate views and which together with the detailed description below are incorporated in and form part of the specification, serve to further illustrate various embodiments and to explain various principles and advantages all in accordance with the invention.

FIG. 1 is a block diagram showing a wireless communication network in which various embodiments of the invention may function.

FIG. 2 is a flowchart of a method of tracking user behavior in a wireless communication network, in accordance with an embodiment of the invention.

FIG. 3 is a flowchart of a method of presenting content to one or more users in a wireless communication network, in accordance with an embodiment of the invention.

FIG. 4 is a flowchart of a method of providing content to one or more users in a wireless communication network, in accordance with another embodiment of the invention.

FIG. 5 is a block diagram of a system for tracking user behavior in a wireless communication network, in accordance with an embodiment of the invention.

FIG. 6 is a block diagram showing elements of a content distribution module, in accordance with an embodiment of the invention.

FIG. 7 is a block diagram showing an anchor datapath gateway for tracking user behavior in a wireless communication network, in accordance with an embodiment of the invention.

Skilled artisans will appreciate that elements in the figures are illustrated for simplicity and clarity and have not necessarily been drawn to scale. For example, the dimensions of some of the elements in the figures may be exaggerated relative to other elements to help to improve understanding of embodiments of the invention.

### DETAILED DESCRIPTION OF THE INVENTION

Before describing in detail embodiments that are in accordance with the invention, it should be observed that the embodiments reside primarily in combinations of method steps, system and apparatus components related to tracking user behavior in a wireless communication network. Accordingly, the apparatus and system components and method steps have been represented where appropriate by conventional symbols in the drawings, showing only those specific details that are pertinent to understanding the embodiments of the invention so as not to obscure the disclosure with details that will be readily apparent to those of ordinary skill in the art having the benefit of the description herein.

In this document, relational terms such as first and second, top and bottom, and the like may be used solely to distinguish one entity or action from another entity or action without necessarily requiring or implying any actual such relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “comprises . . . a” does not, without more constraints, preclude the existence of additional identical elements in the process, method, article, or apparatus that comprises the element.

Various embodiments of the invention provide methods, system and apparatus for tracking user behavior in a wireless communication network. One or more data packets communicated between one or more devices and one or more data servers is monitored at an anchor datapath gateway in the wireless communication network. Thereafter, the monitored data packets are used to create one or more profiles for each of one or more users using the one or more devices. The one or more profiles are used by one or more content providers to provide content to the one or more users.

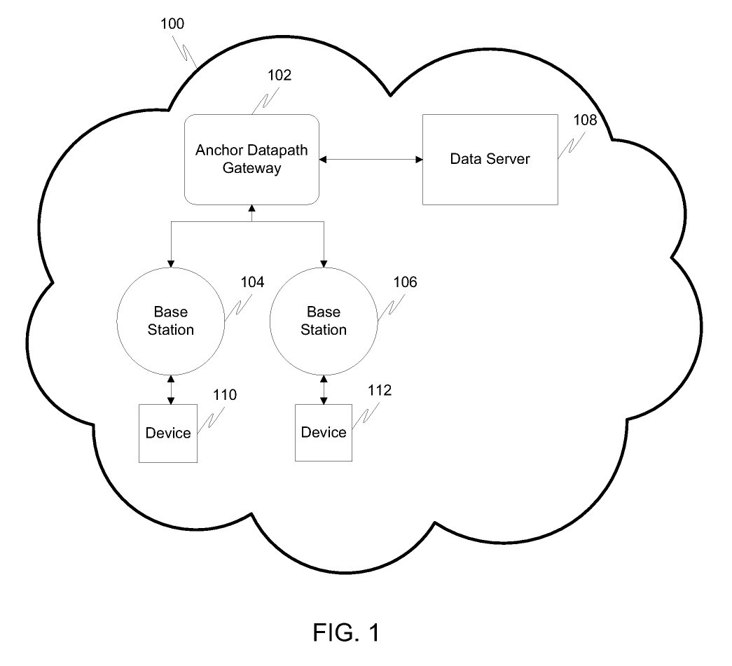

FIG. 1 is a block diagram showing a wireless communication network 100 in which various embodiments of the invention may function. Examples of wireless communication network 100 may include, but are not limited to, a Worldwide Interoperability for Microwave Access (WiMAX) communication network, a 3rd Generation Partnership Project (3GPP) network including 3GPP Long Term Evolution (LTE) network, a 3rd Generation Partnership Project 2 (3GPP2) network including 3GPP2 Ultra Mobile Broadband (UMB) network, a Wireless Fidelity (WiFi) network, and any variant of Orthogonal Frequency Division Multiple Access (OFDMA) communication network having a backhaul link.

Wireless communication network 100 includes an anchor datapath gateway 102, one or more Base Stations (BSs) (for example, a BS 104 and a BS 106), and a data server 108. Anchor datapath gateway 102 may be an Access Service Network (ASN) controller, if wireless communication network 100 is a WiMAX communication network. It will be apparent to a person skilled in the art that wireless communication network 100 may include a plurality of anchor datapath gateways and a plurality of data servers. The one or more BSs further communicate with one or more devices (for example, a device 110 and a device 112). BS 104 communicates with device 110 and BS 106 communicates with device 112. Examples of a device may include, but are not limited to Personal Computers (PC), laptops, mobile phones, Personal Digital Assistants (PDA), and personal communicators. The one or more devices are used by one or more users to request data from data server 108. Data requests generated from the one or more devices are routed through the one or more Base Stations and anchor datapath gateway 102. Thereafter, data server 108 provides data requested by the one or more users at the one or more devices through anchor datapath gateway 102.

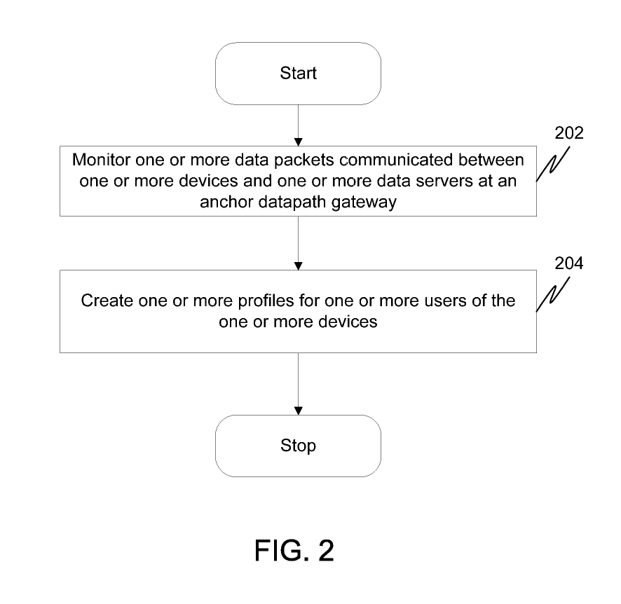

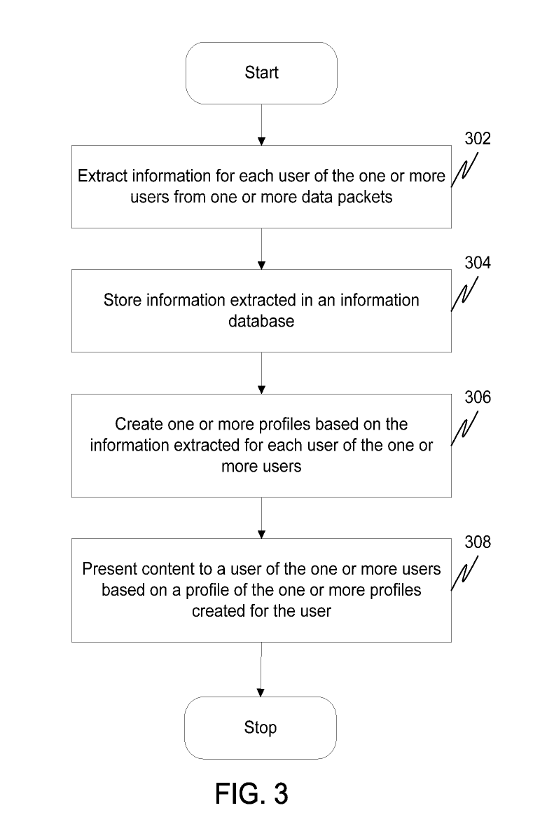

FIG. 2 is a flowchart of a method of tracking user behavior in wireless communication network 100, in accordance with an embodiment of the invention. In wireless communication network 100, data packets are communicated between one or more devices and one or more data servers through an anchor datapath gateway. The one or more devices are used by one or more users. In an embodiment, the anchor datapath gateway is an ASN controller, if wireless communication network 100 is a WiMAX communication network. At step 202, the one or more data packets communicated between the one or more devices and the one or more data servers are monitored at the anchor datapath gateway. The data packets may be transmitted from the one or more devices to the one or more data servers or from the one or more data servers to the one or more devices. While monitoring the one or more data packets at the anchor datapath gateway, information for each user of the one or more users is extracted from the one or more data packets. The information extracted for a user may include, but is not limited to browsing activity of the user, video usage patterns of the user, search keywords used by the user, time spent at a web site by the user, content uploaded by the user, content downloaded by the user, and e-commerce activity of the user. This is further explained in detail in conjunction with FIG. 3.

Thereafter, at step 204, one or more profiles for each of the one or more users is created in response to monitoring the one or more data packets. A profile of the one or more profiles created for a user of the one or more users includes information specific to the user. This is further explained in detail in conjunction with FIG. 3.

Since, each of the one or more data packets routed through the anchor datapath gateway is monitored, sufficient and accurate information specific to each of the one or more users can be extracted.

FIG. 3 is a flowchart of a method of presenting content to one or more users in wireless communication network 100, in accordance with an embodiment of the invention. One or more data packets communicated between one or more devices and one or more data servers are routed through an anchor datapath gateway. While routing the one or more data packets, at step 302, information for each of the one or more users is extracted from one or more data packets at the anchor datapath gateway. The extracted information may include, but is not limited to browsing activity of the user, video usage patterns of the user, search keywords used by the user, time spent at a web site by the user, content uploaded by the user, content downloaded by the user, location of a user while browsing a specific content, and e-commerce activity of the user. Thereafter, at step 304, the information extracted for each user of the one or more users is stored in an information database.

At step 306, one or more profiling algorithms are applied to the information stored in the information database to create one or more profiles for the one or more users. In another embodiment, one or more profiling algorithms may use additional information such as, but not limited to time of day, age of a user, sex of a user, and location of a user to create a profile for the user. The additional information of the user may be obtained during the registration process when the user logs into wireless communication network 100.

The one or more profiles are then utilized by one or more content providers to present content to a user of the one or more users based on a profile of the one or more profiles created for the user at step 308. The content presented to the one or more users may include, but is not limited to one or more advertisements, news articles, weather reports, and location based service content.

As an example of the method given above, consider a situation, where a user logs on to wireless communication network 100 using device 110 to browse web pages related to books. For browsing the web pages, the user transmits one or more data packets. The anchor datapath gateway extracts information of the user from the one or more data packets. Based on the information extracted, the anchor datapath gateway creates a profile for the user. The profile of the user specifies the interests of the user, i.e., reading books, types of books read, and price range of books bought by the user. Therefore, by using the profile, a content provider can determine that the user is interested in reading books. Further, the content provider may determine that the user purchases books mostly related to psychology and between the price range: $50 to $200. This information may be stored by the content provider for future reference. Based on this information, the content provider supplements data requested by the user with advertisements related to psychological books between the price range: $50 to $200. Additionally, the content provider may also provide advertisements of book stores in the vicinity of the user where psychological books are available. The vicinity of the user may be established during the registration process, when the user logs in to wireless communication network 100.

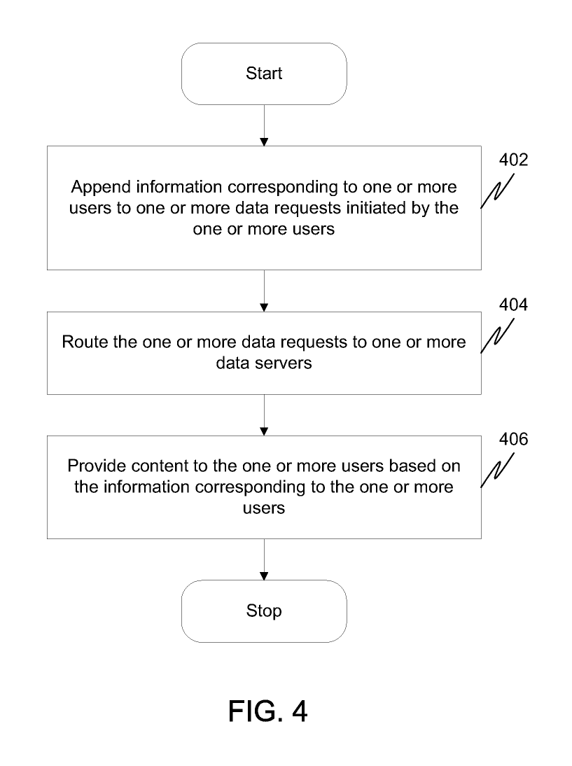

FIG. 4 is a flowchart of a method of providing content to one or more users in wireless communication network 100, in accordance with another embodiment of the invention. One or more users initiate one or more data requests in wireless communication network 100. The one or more data requests are received at an anchor datapath gateway. At step 402, information corresponding to the one or more users is appended to the one or more data requests at the anchor datapath gateway. The information corresponding to the one or more users is extracted from one or more data packets in the one or more data requests. The extracted information may include, but is not limited to browsing activity of the user, video usage patterns of the user, search keywords used by the user, time spent at a web site by the user, content uploaded by the user, content downloaded by the user, location of a user while surfing a specific content, and e-commerce activity of the user. This has been explained in detail in conjunction with FIG. 3

The one or more data requests are then routed to one or more content servers at step 404. Thereafter, at step 406, the one or more content servers provide content to the one or more users based on information corresponding to the one or more users. The content provided by the one or more data servers is in addition to data requested in the one or more data requests. For example, consider a user requesting content for an eatery. The anchor datapath gateway appends information corresponding to the user to the request prior to routing to a content server. The information is extracted based on prior browsing activity of the user and may indicate that the user is particularly fond of Mexican food. Since the data server now possesses this information, the data server may supplement data on eateries that the user requested with advertisements relating to eateries serving Mexican food. Additionally, depending on the age of the user, advertisements of a fast food outlet serving Mexican food may be shown to a teen and content relating to exclusive restaurants may be shown to mature adults.

In an embodiment, a content server of the one or more content servers may further route the information corresponding to a user of the one or more users to external content providers. The external content providers may use the information to locate content specific to the user and deliver the content to the content server. The content server subsequently supplements the data requested by the one or more users with the content provided by the external content providers. In yet another embodiment, the one or more external content providers may directly present the content to the user.

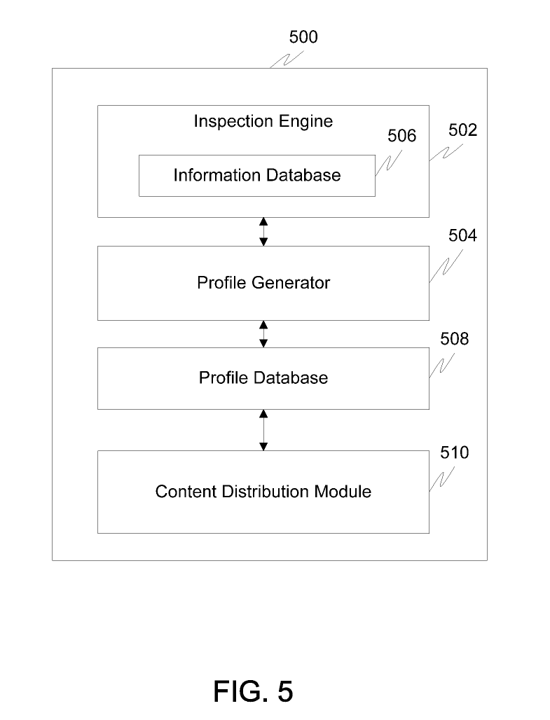

FIG. 5 is a block diagram of a system 500 for tracking user behavior in a wireless communication network 100, in accordance with an embodiment of the invention. System 500 includes an inspection engine 502 and a profile generator 504. Inspection engine 502 monitors one or more data packets communicated between one or more devices and one or more data servers at an anchor datapath gateway in wireless communication network 100. On monitoring the one or more data packets, inspection engine 502 extracts information for each user of the one or more users. Inspection engine 502 then stores the information extracted for the one or more users in an information database 506.

Thereafter, profile generator 504 creates one or more profiles for the one or more users in response to monitoring the one or more data packets. The one or more profiles for the one or more users may be created by using one or more profiling algorithms on the information stored in information database 506. The one or more profiles are thereafter stored in a profile database 508.

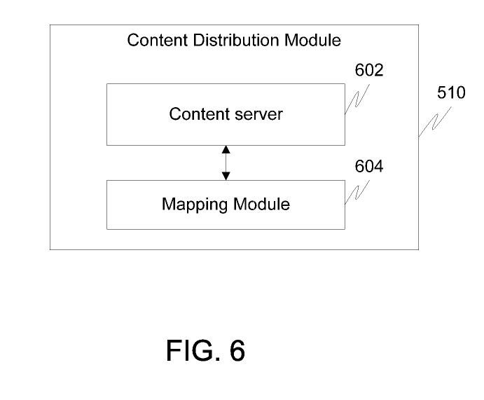

As each of the one or more profiles in profile database 508 accurately provide information regarding interests, preferences, and behavior of the one or more users, profile database 508 may be accessed by a content distribution module 510 to retrieve information corresponding to each of the one or more users. Content distribution module 510 is further explained in detail in conjunction with FIG. 6. In an embodiment, external content providers access profile database 508.

Therefore, the one or more profiles created for the one or more users enables content distribution module 510 to present content, which is accurately targeted to the one or more users. Moreover, the content can be provided to the one or more users effectively and profitably.

FIG. 6 is a block diagram showing elements of content distribution module 510, in accordance with an embodiment of the invention. Content distribution module 510 includes a content server 602 and a mapping module 604. Content server 602 stores content provided by a plurality of content providers. After the one or more profiles are accessed by content distribution module 510, mapping module 604 maps content to the one or more profiles. When mapping module 604 finds a match between a profile of the one or more profiles of a user of the one or more users and one or more parts of the content stored in content server 602, content distribution module 510 presents the one or more parts of the content to the user.

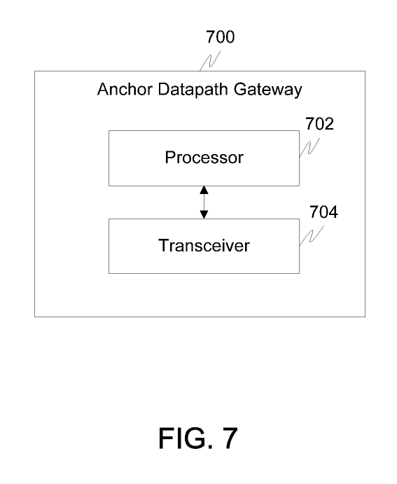

FIG. 7 is a block diagram showing an anchor datapath gateway 700 for tracking user behavior in wireless communication network 100, in accordance with an embodiment of the invention. Anchor datapath gateway 700 includes a processor 702 and a transceiver 704. Transceiver 704 receives one or more messages sent by at least one of one or more users and one or more data servers. A message sent by a user of the one or more users may be a data request. Similarly, a message sent by a data server of the one or more data servers may include data requested by the user in the data request. Thereafter, processor 702 monitors one or more data packets in the one or more messages. While monitoring the one or more data packets, processor 702 extracts information for each user of the one or more users. Processor 702 may store the information in a memory of anchor datapath gateway 700. Processor 702 uses the information to create one or more profiles for each user of the one or more users. Thereafter, processor 702 stores the one or more profiles in the memory.

Processor 702 then appends the information corresponding to a user of the one or more users to one or more data requests initiated by the user. The one or more data requests are subsequently routed by transceiver 704 to one or more data servers.

In an embodiment, processor 702 may store content provided by a plurality of content providers in the memory. In this case, processor 702 may map the content to the one or more profiles. When processor 702 finds a match between one or more parts of the content and a profile of the one or more profile, processor 702 may present the one or more parts of the content to a user for whom the profile was created.

Various embodiments of the invention provide methods, systems, and apparatuses to track user behavior in a wireless communication network. In this method, profiles are created for one or more users based on information extracted from data packets communicated between one or more devices used by the one or more users and one or more data servers at an anchor datapath gateway. Therefore, the one or more profiles enable content providers to present content, which is accurately targeted to the one or more users. Moreover, the content can be provided to the one or more users effectively and profitably.

In the foregoing specification, specific embodiments of the invention have been described. However, one of ordinary skill in the art appreciates that various modifications and changes can be made without departing from the scope of the invention as set forth in the claims below. Accordingly, the specification and figures are to be regarded in an illustrative rather than a restrictive sense, and all such modifications are intended to be included within the scope of the invention. The benefits, advantages, solutions to problems, and any element(s) that may cause any benefit, advantage, or solution to occur or become more pronounced are not to be construed as a critical, required, or essential features or elements of any or all the claims. The invention is defined solely by the appended claims including any amendments made during the pendency of this application and all equivalents of those claims as issued.

What is claimed is:

1. A method of tracking user behavior in a wireless communication network, the method comprising:
monitoring at least one data packet communicated between at least one device and at least one data server at an anchor datapath gateway in the wireless communication network; and
creating at least one profile for at least one user in response to monitoring the at least one data packet, wherein the at least one device is used by the at least one user.

2. The method of claim 1 further comprising presenting content to a user of the at least one user based on a profile of the at least one profile created for the user.

3. The method of claim 2, wherein the content is provided by a plurality of content providers.

4. The method of claim 2, wherein the content comprises at least one of advertisements, news articles, weather reports, and location based service content.

5. The method of claim 1, wherein monitoring comprises extracting information for each user of the at least one user from the at least one data packet.

6. The method of claim 5, wherein the information extracted for each user of the at least one user is stored in an information database.

7. The method of claim 5, wherein the at least one profile is created based on the information extracted for each user of the at least one user.

8. The method of claim 5, wherein the information extracted for a user of the at least one user comprises at least one of browsing activity of the user, video usage patterns of the user, search keywords used by the user, content downloaded by the user, content uploaded by the user, location of the user, and ecommerce activity of the user.

9. The method of claim 1, wherein the wireless communication network is one of a Worldwide Interoperability for Microwave Access (WiMAX) communication network, 3rd Generation Partnership Project (3GPP) Long Term Evolution (LTE) network, 3rd Generation Partnership Project 2 (3GPP2) Ultra Mobile Broadband (UMB) network, Wireless Fidelity (WiFi) network, and Orthogonal Frequency Division Multiple Access (OFDMA) communication network having a backhaul link.

10. A method of providing content to at least one user in a wireless communication network, the method comprising:
appending information corresponding to at least one user to at least one data request at an anchor datapath gateway, wherein the at least one data request is initiated by the at least one user;
routing the at least one data request to at least one content server; and
providing content to the at least one user based on the information corresponding to the at least one user, wherein the content is provided in addition to data requested in the at least one data request.

11. The method of claim 10, wherein the information is at least one of browsing activity of the user, video usage patterns of the user, search keywords used by the user, content downloaded by the user, content uploaded by the user, location of the user, and ecommerce activity of the user.

12. The method of claim 10, wherein content comprises at least one of advertisements, news articles, weather reports, and location based service content.

13. A system for tracking user behavior in a wireless communication network, the system comprising:
an inspection engine to monitor at least one data packet communicated between at least one device and at least one data server at an anchor datapath gateway in the wireless communication network; and
a profile generator to create at least one profile for at least one user in response to monitoring the at least one data packet, wherein the at least one device is used by the at least one user.

14. The system of claim 13, wherein the inspection engine extracts information for each user of the at least one user from the at least one data packet.

15. The system of claim 14, wherein the inspection engine comprises an information database to store the information extracted for each user of the at least one user.

16. The system of claim 13 further comprising a profile database for storing the at least one profile.

17. The system of claim 13 further comprising a content distribution module to present at least a part of content to a user of the at least one user based on a profile of the at least one profile created for the user.

18. The system of claim 17, wherein the content distribution module comprises a content server for storing the content, wherein the content is provided by a plurality of content providers.

19. The system of claim 17, wherein the content distribution module comprises a mapping module to map the content to the at least one profile.

20. An anchor datapath gateway for tracking user behavior in a wireless communication network, the anchor datapath gateway comprising:
a processor configured to:
monitor at least one data packet communicated between at least one device and at least one data server;
create at least one profile for at least one user in response to monitoring the at least one data packet, wherein the at least one device is used by the at least one user; and
a transceiver configured to receive at least one message sent by at least one of the at least one user and the at least one data server, wherein the at least one message comprise the one or more data packets.

21. The anchor datapath gateway of claim 20, wherein the processor is further configured to extract information for each user of the at least one user from the at least one data packet.

22. The anchor datapath gateway of claim 21, wherein the processor is further configured to append information extracted for a user of the at least one user to a data request of the at least one data request initiated by the user.

23. The anchor datapath gateway of claim 22, wherein the transceiver is further configured to route the data request to at least one content server.

24. The anchor datapath gateway of claim 21, wherein the processor is further configured to store the information extracted for each user of the at least one user.

25. The anchor datapath gateway of claim 20, wherein the processor is further configured to store the at least one profile.

26. The anchor datapath gateway of claim 20, wherein the processor is further configured to store content provided by a plurality of content providers.

27. The anchor datapath gateway of claim 26, wherein the processor is further configured to map the content to the at least one profile.

28. The anchor datapath gateway of claim 27, wherein the processor is further configured to present at least one part of the content to a user of the at least one user, the at least one part of the content maps to a profile of the at least one profile created for the user.
